(19) United States
(12) Patent Application Publication
(10) Pub. No.: US 2022/0155349 A1
(43) Pub. Date: May 19, 2022

(54) Vertical Probe Head

(71) Applicant: Technoprobe, S.p.A., Cernusco Lombardone (LC) (IT)

(72) Inventor: Flavio MAGGIONI, Cernusco Lombardone LC (IT)

(21) Appl. No.: 17/591,374

(22) Filed: Feb. 2, 2022

Related U.S. Application Data
(63) Continuation-in-part of application No. PCT/EP2020/071901, filed on Aug. 4, 2020.

(30) Foreign Application Priority Data
Aug. 7, 2019 (IT) 102019000014211

(51) Int. Cl. G01R 1/073; G01R 3/00; G01R 31/28

(52) U.S. Cl. CPC G01R 1/07371; G01R 31/2886; G01R 1/07314; G01R 3/00

(57) ABSTRACT

A probe head adapted to verify the operation of a device to be tested integrated on a semiconductor wafer comprises at least one guide provided with a plurality of guide holes adapted to house a plurality of contact probes. Conveniently, the guide is made of a material suitable for manufacturing integrated circuits and comprises circuit components integrated therein, such guide being an electronically active element of the probe head.

### RELATED APPLICATIONS

The present application is a Continuation-in-Part (CIP) application of Int. Pat. App. No. PCT/EP2020/071901, filed Aug. 4, 2020, which claims priority to Italian Pat. App. No. 102019000014211, filed Aug. 7, 2019, the entire disclosures of which applications are hereby incorporated herein by reference.

### TECHNICAL FIELD

The present disclosure refers to a vertical probe head for testing electronic devices integrated on a semiconductor substrate, and the following description is made with reference to this field of application with the only purpose of simplifying the exposition thereof.

### BACKGROUND

As it is well known, a probe head is an electronic device adapted to electrically connect a plurality of contact pads of a microstructure, such as a device integrated on a semiconductor wafer, with corresponding channels of a testing apparatus that performs the functionality testing thereof, in particular electric, or generically the test.

The test, which is performed on integrated devices, is particularly useful for detecting and isolating defective circuits as early as in the production phase. Normally, probe heads are therefore used for the electric test of devices that are integrated on wafers before cutting and assembling them inside a containment package.

In general, a probe head comprises a plurality of contact elements or contact probes which are hold by at least one guide and by at least one pair of guides (or supports) which are substantially plate-shaped and parallel to each other. Such guides are provided with specific guide holes and are spaced from each other so as to create a free zone or air gap for the movement and the possible bending of the contact probes, which are slidably housed in such guide holes. The pair of guides comprises an upper guide and a lower guide, which are both provided with guide holes within which the contact probes axially slide, said probes being usually made of special alloys with good electrical and mechanical properties.

The proper connection between the contact probes and the contact pads of the device under test is ensured by the pressure of the probe head on the device itself, wherein the contact probes undergo, during said pressing contact, a bending inside the air gap between the guides and a sliding inside the respective guide holes. Probe heads of this type are commonly called as “vertical probe heads”.

Substantially, the vertical probe heads have an air gap in which a bending of the contact probes occurs, wherein said bending can be helped by a suitable configuration of the probes themselves or of the guides thereof, as schematically illustrated in FIG. 1.

In particular, in FIG. 1 a vertical probe head is schematically illustrated and globally indicated with 1. The probe head 1 comprises a plurality of contact probes 2 housed in at least one upper guide 3, usually indicated as an “upper die” and a lower guide 4, usually indicated as a “lower die”, said guides being plate-shaped, parallel to each other and separated by an air zone 7. The upper 3 and lower 4 guides comprise respective guide holes 3A and 4A within which the contact probes 2 slide.

Each contact probe 2 has an end zone or region which ends with a contact tip 2A intended for abutting onto a respective contact pad 6A of a plurality of contact pads of a device to be tested integrated on a semiconductor wafer 6, so as to perform the mechanical and electrical contact between such device to be tested and a testing apparatus (not represented) of which such probe head 1 is a terminal element.

In the example of FIG. 1, every contact probe 2 also has a further end zone or region which ends with a so-called contact head 2B towards a respective contact pad 5A of a plurality of contact pads of a space transformer 5. The proper electrical contact between contact probes 2 and space transformer 5 is assured by the pressure abutment of the contact heads 2B of the contact probes 2 onto the contact pads 5A of the space transformer 5 in an analogous manner as the contact between the contact tips 2A of the contact probes 2 and the contact pads 6A of the device to be tested.

In general, the routing paths inside the space transformers, as well as the circuit layout of the PCBs interfacing the probe head with the test apparatus, are very complex and it is thus desirable to reduce such complexity.

Furthermore, in order to increase the performances of the probe head, it is desirable that the probe head itself is able to perform operations on the signals carried by the contact probes thereof, preferably in proximity to the device to be tested.

### SUMMARY

The probe head has structural and functional features such as to allow overcoming the limitations and drawbacks still affecting the probe heads according to the prior art, in particular able to perform operations, even complex ones, on the signals carried by the contact probes thereof.

According to an aspect of the disclosure the probe head takes advantage of the technology of the integrated circuits on a semiconductor substrate in the manufacturing of a guide of such a probe head, such that said guide acts on the one hand as a housing element of the contact probes, and, on the other hand, comprises active circuitry to perform operations on the signals carried by such contact probes, therefore acting as an electronically active element of the probe head which comprises it. In other words, the guide (preferably the lower guide) of the probe head is a circuit board comprising on one the hand integrated circuits and on the other hand a plurality of guide holes for housing the contact probes.

The probe head is adapted to verify the operation of a device to be tested and comprises at least one guide provided with a plurality of guide holes adapted to house a plurality of contact probes, such probe head being characterized in that the guide is made of a material suitable for manufacturing integrated circuits and in that the guide comprises circuit components integrated therein, such guide being an electrically active element of the probe head.

According to one aspect of the present disclosure, the material forming the guide can be selected from silicon and glassy materials, preferably silicon.

According to another aspect of the present disclosure, at least one guide hole of the guide can comprise a metallization. In particular, such metallization can cover at least one portion of an internal surface of the guide hole. Still more in particular, the guide can comprise a pad which is electrically connected to the metallization.

According to another aspect of the present disclosure, the guide can comprise at least one conductive track which extends from at least one of the guide holes and/or connects the circuit components of the guide.

According to yet another aspect of the present disclosure, at least such guide can comprise at least one conductive portion which includes and electrically connects the holes of at least one group of the guide holes to each other and is adapted to contact a corresponding group of the contact probes, such contact probes of such corresponding group, short-circuited to each other by the conductive portion, being adapted to carry a same type of signal.

In particular, the guide can comprise at least one common pad which is connected to the at least one conductive portion.

According to one aspect of the present disclosure, the at least one conductive portion can be arranged on at least one face of the guide, wherein guide holes which are not to be short-circuited are electrically insulated from the at least one conductive portion by means of non-conductive zones in the guide.

Furthermore, the at least one conductive portion can be in the form of a plurality of conductive layers, wherein consecutive conductive layers are separated by non-conductive layers.

According to another aspect of the present disclosure, the guide can be a lower guide of the probe head, which also comprises at least one upper guide parallel to the lower guide and separated therefrom by means of an air zone or gap, such lower guide being in proximity to the device to be tested.

According to another aspect of the present disclosure, the circuit components integrated in the guide can comprise at least one active component.

More in particular, the guide can comprise active circuits which are configured to perform complex operations on signals carried by the contact probes.

According to another aspect of the present disclosure, the integrated circuit components can be included in circuits formed by means of the integrated circuit technology on a semiconductor substrate.

The present disclosure also relates to a method for manufacturing a probe head adapted to verify the operation of a device to be tested, comprising the step of:

providing at least one guide provided with a plurality of guide holes adapted to house a plurality of contact probes,

the method of the present disclosure being characterized by the step of:

integrating circuit components in the guide so as to make such guide an electronically active element of the probe head,

wherein the guide is made of a material suitable for housing integrated circuits.

According to one aspect of the present disclosure, the method can further comprise a step of forming, by means of the integrated circuits technology, at least one conductive portion and/or at least one conductive track.

The characteristics and advantages of the probe head and of the method according to the disclosure will be apparent from the description, made hereinafter, of an embodiment thereof, given by way of indicative and non-limiting example, with reference to the enclosed drawings.

### BRIEF DESCRIPTION OF THE DRAWINGS

FIG. 1 schematically shows a probe head according to the prior art;

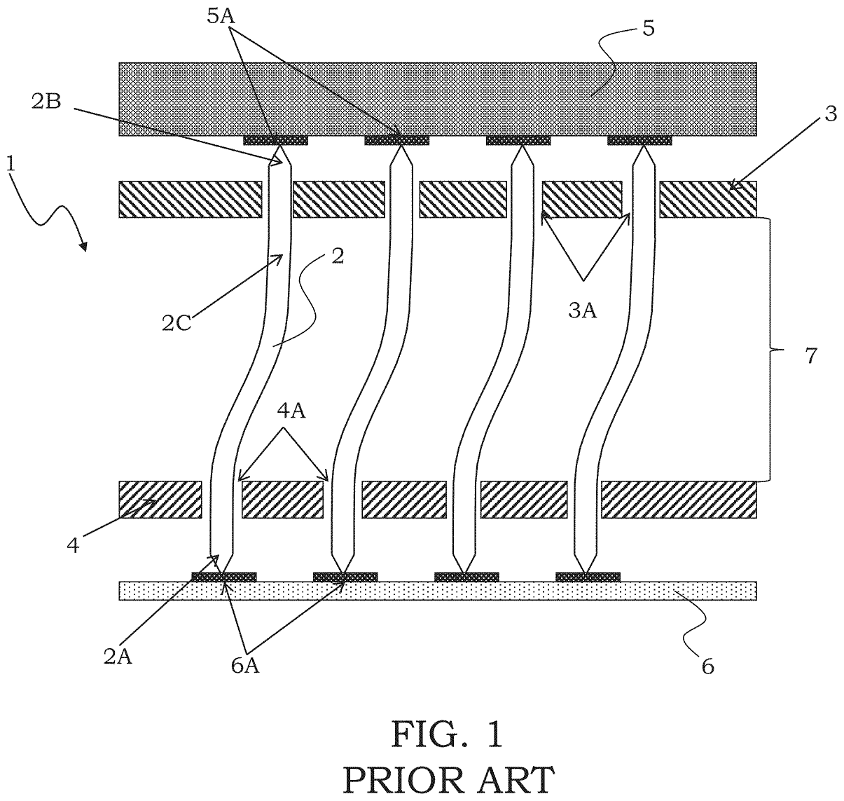

FIG. 2 schematically shows a probe head according to an embodiment of the present disclosure; and

FIG. 3 schematically shows a top view of a guide of the probe head according to the present disclosure.

### DETAILED DESCRIPTION

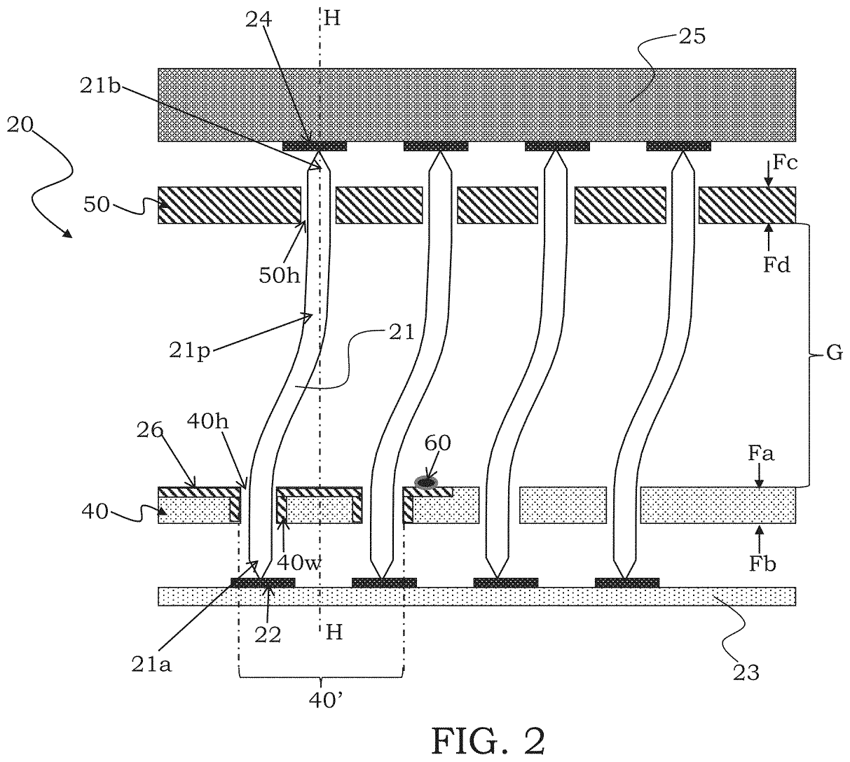

With reference to those Figures, and in particular to the example of FIG. 2, a probe head for testing electronic devices integrated on a semiconductor wafer according to the present disclosure is globally and schematically indicated with 20.

It is worth noting that the Figures represent schematic views and are not drawn to scale, but instead they are drawn so as to emphasize the important features of the disclosure. Moreover, in the Figures, the different elements are depicted in a schematic manner, their shape varying depending on the application desired. It is also noted that in the Figures the same reference numbers refer to elements that are identical in shape or function. Finally, particular features described in relation to an embodiment illustrated in a Figure are also applicable to the other embodiments illustrated in the other Figures.

The probe head 20 comprises at least one guide 40, which is a lower guide in the example of FIG. 2, said guide 40 being provided with a plurality of guide holes 40h adapted to house a corresponding plurality of contact probes.

In the probe head 20, contact probes adapted to carry input/output operating signals towards/from a device to be tested are present, as well as contact probes adapted to carry power signals (called herein “power probes”) and contact probes adapted to carry the ground (called herein “ground probes”), as known in the field, such contact probes being all indicated herein with the reference number 21. Although FIG. 2 shows only four contact probes 21, it is obvious that the probe head 20 can comprise any number of contact probes, such Figure being provided only by way of an indicative and non-limiting example of the present disclosure.

In particular, the contact probes 21 comprise a body 21p which extends along a longitudinal axis H-H between a first end portion 21a and a second end portion 21b. The first end portion 21a is adapted to contact the contact pads 22 of a device to be tested integrated on a semiconductor wafer 23, while the second end portion 21b is generally adapted to contact the contact pads 24 of a space transformer 25 associated with the probe head 20.

According to the embodiment illustrated in FIG. 2, the probe head 20 comprises, in addition to the guide 40 (which is a lower guide) also an upper guide 50, such guides being spaced apart by an air zone or gap G. Obviously, the number of guides may vary according to the needs and/or circumstances, the Figures being provided only by way of a non-limiting example.

Advantageously according to the present disclosure, at least one of the guides of the probe head 20 (the lower guide 40 in the example of FIG. 2) is made of a material suitable for manufacturing integrated circuits, such as for example a semiconductor substrate such as silicon, germanium, or also glassy materials and organic materials, preferably silicon.

In this way, by taking advantage of the integrated circuit technologies on a semiconductor substrate for manufacturing the guide 40, integrated circuit components 60, even active ones, are housed in such guide 40, as will be described in detail below. The guide 40 is thus both an electrically active element of the probe head 20 and a mechanical support of the contact probes 21 thereof.

In other words, the guide 40 is a circuit board comprising at least one integrated circuit, such board further comprising the guide holes 40h for housing the contact probes 21, such that the guide 40 is able and conFigured to perform operations on the signals carried by such contact probes 21 by means of the circuit components 60 integrated therein.

Conveniently, the guide 40 houses active circuit components 60a, such as for example transistors. The usage of a semiconductor substrate as a starting material allows the active circuit components 60a to be easily integrated in the guide 40, for example by means of suitable doping techniques in order to create the active zones of such active components 60a (for example the transistor gates). In this way, the guide 40 is able to house active circuits, even complex ones.

In other words, the circuit components 60 integrated in the guide 40 are included in circuits, also very complex, formed by means of the technology of the circuits integrated on a semiconductor substrate, such circuits being able to perform operations, also complex ones, on the signals carried by the contact probes 21.

As a way of example, the circuits of the guide 40 can include signal processing circuits, logic gates, multiplexers, filtering elements, amplifiers and similar. In particular, such circuits may perform a pre-processing operation of the signals, in this way easing the operation of the testing apparatus connected to the probe head 20.

The guide 40 can also comprise passive circuit components 60b. As a way of example, it is often desirable to perform a filtering operation on the signals carried by the contact probes 21 in order to improve the frequency performances of the probe head 20, so that the guide 40 can comprise suitable filtering capacitors. In a similar way, in addition or as an alternative to the filtering capacitors, the guide 40 can also comprise a resistor, an inductor, a relay or a combination thereof, such circuit elements acting so as to improve the overall performances of the probe head 20.

Obviously, the guide 40 is not limited to the above-described circuit components and it can comprise any suitable component.

It should be noted that the present disclosure is herein disclosed in relation to a preferred embodiment thereof in which the guide provided with integrated active circuitry is the lower guide 40, although the same inventive concepts can be applied to the upper guide 50 or to any other guide of the probe head 20. However, it is noted that the circuitry integration in the lower guide 40 is preferred since the integrated circuit components 60 are in this way closer to the device to be tested, thus contributing to improve the performances of the probe head 20, in particular in the case of filtering operations of the signals carried by the contact probes 21.

Referring again to FIG. 2, at least one guide hole 40h of the guide 40 comprises a metallization which covers at least one portion 40w of an inner surface thereof. More preferably, the inner surface of the guide hole is entirely covered by the metallization, the portion 40w thus corresponding with the entire inner surface of the hole. In this way, for example, the presence of at least one metalized guide hole allows the signal carried by a contact probe 21 housed in such particular guide hole to be extracted already in the guide 40. Furthermore, the metallization of at least one guide hole allows the contact probes 21 to be electrically connected with the circuits integrated in the guide 40.

During the formation of an integrated circuit in the guide 40, it is also possible to form also at least one conductive portion 26 which includes a group 40′ of the guide holes 40h. In other words, the conductive portion 26 covers an area of the guide 40 which includes the group 40′ of the guide holes 40h, which are thus formed at such area. In particular, the guide holes of the group 40′ are electrically connected to each other by the conductive portion 26 and house a corresponding group of contact probes 21, which are thus contacted by such conductive portion 26. The contact probes of such corresponding group are adapted to carry a same type of signal, for example they are ground probes, power probes or probes adapted to carry input/output operating signals towards/from the device to be tested.

Therefore, the conductive portion 26 forms a common conductive plane for the contact probes 21 housed in the guide holes of the group 40′, such contact probes 21 being electrically connected to each other by means of this common conductive plane, with which they are all in contact. In other words, in the probe head 20, the contact probes 21 housed in the group 40′ of the guide holes 40h are short-circuited to each other and, in the case of ground or power probes, this leads to a consequent elimination of the interferences on the operating signals carried by the other probes and to an overall improvement of the frequency performances of the probe head 20.

As illustrated in FIG. 2, the conductive portion 26 is arranged on at least one face of the guide 40, in particular on the face Fa which is an upper face of the guide 40 according to the local reference system of the Figures. Obviously, the conductive portion 26 can be formed on a face Fb, which is a face opposite to the face Fa and is thus a lower face of the guide 40 according to the local reference system of the Figures, as well as on both faces Fa and Fb.

As an alternative, in one embodiment which is not illustrated in the Figures, the conductive portion 26 is in the form of a plurality of conductive layers, some of which can be embedded in the guide 40, wherein consecutive conductive layers are separated by non-conductive layers.

In any case, guide holes which are not to be short-circuited are electrically insulated from the conductive portion 26 by means of non-conductive zones in the guide 40. In case that contact probes which are not to be short-circuited are very close to probes to be short-circuited, for example alternated to each other, the conductive portion 26 is locally interrupted by the non-conductive zones so as not to electrically connect the contact probes which are not to be short-circuited.

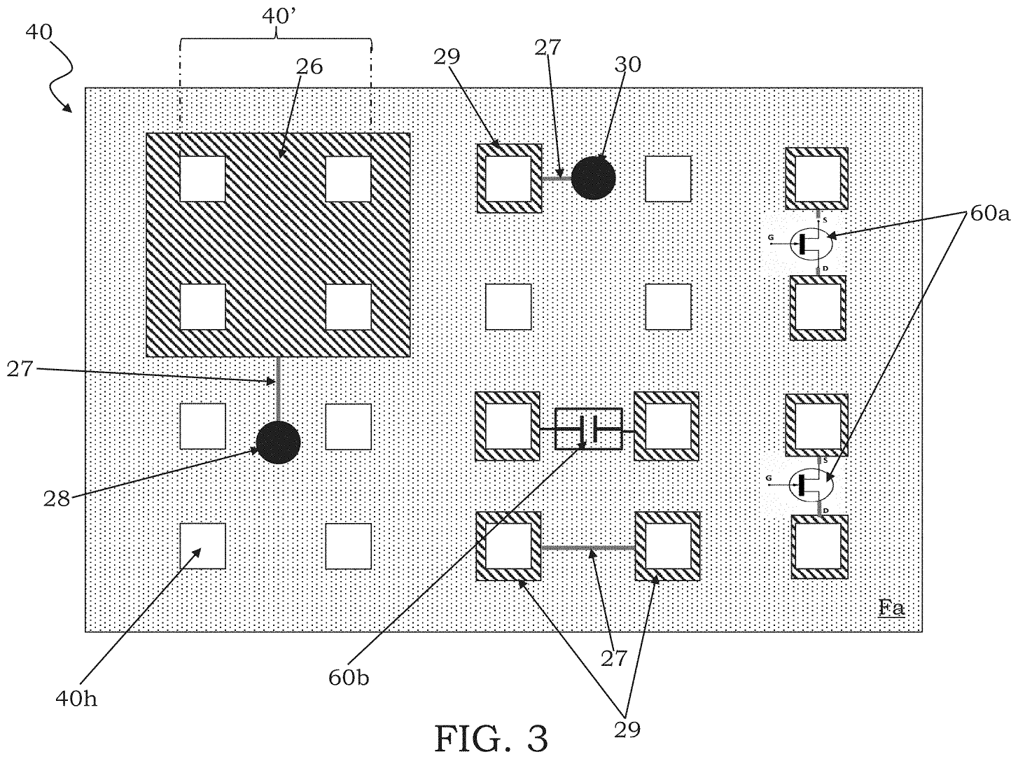

FIG. 3 shows a schematic top view of the guide 40, in particular of the face Fa thereof, and schematically illustrates that the circuits formed on the guide 40 comprise a plurality of conductive tracks 27 which extend from the guide holes 40h (possibly provided with a metallization as above indicated), and/or connect different circuit components 60 to each other, such conductive tracks 27 being both formed on the guide surface 40 and embedded therein.

Referring now in particular to the FIG. 3, in one embodiment of the present disclosure, the guide 40 comprises at least one common pad 28 connected to the conductive portion 26, for example by means of a suitable conductive track of the plurality of conductive tracks 27.

Furthermore, as already previously mentioned and now illustrated more in detail in FIG. 3, the guide 40 also comprises metallizations which metalize single guide holes, such metallizations being indicated herein with the reference number 29.

In one embodiment of the present disclosure, the guide 40 further comprises a pad 30 electrically connected to a single metalized guide hole, wherein such pad 30 can be used for example to monitor the signal carried by a single contact probe.

The guide 40 thus comprises at least one conductive portion 26, which includes a plurality of guide holes 40h, and/or at least one metallization 29, which includes a single guide hole 40h adapted to house a single contact probe 21. As already noted, both the conductive portion 26 and the metallization 29 preferably cover the portion 40w of the internal surface of the guide holes 40h.

The possibility of metalizing single guide holes is furthermore particularly advantageous also in case there is a need to short-circuit two or more contact pads of the device to be tested. In this case, guide holes housing signal contact probes 21 are metalized, such holes being electrically connected to each other by a conductive track 27 (or possibly also by a conductive portion 26), forming a loop-back configuration in which the path of the signals is considerably shortened since they do not pass through all contact elements from and towards the test apparatus but they stop at the guide 40, with consequent advantages in terms of frequency performances of the probe head 20.

As previously mentioned, the present disclosure provides the use of a semiconductor material (which is suitable for circuitry integration) in the manufacturing of the guide 40, which allows to integrate, according to known methods, circuits which are configured to act on the signals carried by the contact probes. As a way of example, as illustrated in FIG. 3, a contact probe can contact the source terminal and another contact probe can contact the drain terminal of a n-Mos transistor integrated in the guide 40.

The present disclosure also refers to a method for manufacturing a probe head 20, such method comprising a preliminary step of providing at least one guide 40, preferably a lower guide but not limited thereto, provided with a plurality of guide holes 40h adapted to house a plurality of contact probes 21.

Suitably, the method of the present disclosure comprises the step of integrating circuit components 60 in the guide 40 so as to make it an electronically active element of the probe head 20.

In particular, the guide 40 is made of a material suitable for housing integrated circuits, such as for example a semiconductor substrate such as silicon, germanium, or also glassy materials, organic materials and other suitable materials, preferably silicon.

The usage of the integrated circuit technologies for forming the guide 40 also allows the conductive tracks 27 and the conductive portions 26 to be formed at the same time. In this way, it is possible to form the metallizations already during the production of the guide 40.

In conclusion, the present disclosure provides a probe head in which the technology of the integrated circuits on a semiconductor substrate is exploited for manufacturing at least one guide thereof, such that said guide acts, on the one hand, as a housing element of the contact probes and, on the other hand, comprises active circuitry to perform operations on the signals carried by such contact probes.

Advantageously according to the present disclosure, the housing of active circuitry, even complex one, in the guide of the probe head is greatly simplified since well-known and efficient technologies are used for integrating such circuitry. In particular, the guide is made of a semiconductor material which is well suitable for integrating active circuit components and thus for forming integrated circuits.

In this way, it is possible to easily and efficiently manufacture a guide for a probe head which, on the one hand, acts as a support and housing element of the contact probes, and, on the other hand, acts as an electronically active element in such probe head, performing operations, even complex ones, on the signals carried by the contact probes.

From the foregoing it will be appreciated that, although specific embodiments of the disclosure have been described herein for purposes of illustration, various modifications may be made without deviating from the spirit and scope of the disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A probe head configured to verify the operation of a device to be tested and comprising:
a plurality of contact probes; and
at least one guide provided with a plurality of guide holes, the guide holes being adapted to house the plurality of contact probes;
wherein the guide is made of a material suitable for manufacturing integrated circuits; and
wherein the guide comprises circuit components integrated therein, so that the guide is an electronically active element of the probe head.

2. The probe head of claim 1, wherein the material forming the guide is selected from silicon and glassy materials.

3. The probe head of claim 1, wherein at least one guide hole of the guide comprises a metallization.

4. The probe head of claim 3, wherein the metallization covers at least one portion of an inner surface of the guide hole.

5. The probe head of claim 3, wherein the guide comprises a pad which is electrically connected to the metallization.

6. The probe head of claim 1, wherein the guide comprises at least one conductive track which extends from at least one of the guide holes.

7. The probe head of claim 1, wherein the guide comprises at least one conductive track which connects the circuit components of the guide.

8. The probe head of claim 1, wherein the guide comprises at least one conductive track which extends from at least one of the guide holes and connects the circuit components of the guide.

9. The probe head of claim 1, wherein the plurality of guide holes includes a first group of guide holes and the plurality of contact probes includes a first group of contact probes adapted to carry a same type of signal; and
wherein the guide comprises at least one conductive portion which includes and electrically connects the guide holes of the first group of guide holes to each other and is adapted to contact the first group of contact probes.

10. The probe head of claim 9, wherein the guide comprises at least one common pad which is connected to said at least one conductive portion.

11. The probe head of claim 9, wherein the at least one conductive portion is arranged on at least one face of the guide.

12. The probe head of claim 9, wherein the guide comprises non-conductive zones which electrically insulate guide holes by the at least one conductive portion so that the guide holes are not short-circuited by the at least one conductive portion.

13. The probe head of claim 9, wherein the at least one conductive portion comprises a plurality of conductive layers and non-conductive layers, consecutive conductive layers being separated by means of a non-conductive layer.

14. The probe head of claim 1, including a lower guide and an upper guide parallel one another and separated by an air zone, the lower guide being the one more in proximity to the device to be tested during the test, wherein the guide is the lower guide.

15. The probe head of claim 1, wherein the circuit components integrated in the guide comprise at least one active component.

16. The probe head of claim 1, wherein the guide comprises active circuits configured to perform complex operations on signals carried by the contact probes.

17. The probe head of claim 1, wherein the integrated circuit components are included in circuits obtained by means of the integrated circuit technology on a semiconductor substrate.

18. A method for manufacturing a probe head configured to verify the operation of a device to be tested, comprising:
providing a plurality of contact probes;
providing at least one guide including a plurality of guide holes adapted to house the plurality of contact probes; and
integrating circuit components in the guide so as to make the guide an electronically active element of the probe head;
wherein the guide is made of a material suitable for housing integrated circuits.

19. The method of claim 18, further comprising forming, by means of the integrated circuits technology, at least one conductive portion on the guide.

20. The method of claim 19, wherein the at least one conductive portion is formed on at least one face of the guide.

21. The method of claim 18, further comprising forming, by means of the integrated circuits technology, at least one conductive track on the guide.

22. The method of claim 18, further comprising forming, by means of the integrated circuits technology, at least one conductive portion and at least one conductive track on the guide.

23. A probe head comprising:
a plurality of contact probes; and
at least one guide provided with a plurality of guide holes, at least one pad and at least one conductive track, the guide holes being adapted to house the plurality of contact probes,
wherein the guide is made of a material suitable for manufacturing integrated circuits selected from silicon and glassy materials; and
wherein the guide comprises:
circuit components integrated therein, so that the guide is an electronically active element of the probe head; and
at least one conductive portion;
wherein at least one guide hole of the guide comprises a metallization which covers at least one portion of an inner surface of the guide hole and is electrically connected to the pad and the at least one conductive track connects the circuit components extending from the guide hole; and
wherein the plurality of guide holes includes a first group of guide holes and the plurality of contact probes includes a first group of contact probes adapted to carry a same type of signal, the at least one conductive portion including and electrically connecting the guide holes of the first group of guide holes to each other and is adapted to contact the first group of contact probes.

24. The probe head of claim 23, wherein the guide comprises at least one common pad which is connected to said at least one conductive portion.

25. The probe head of claim 23, wherein the at least one conductive portion is arranged on at least one face of the guide and wherein the guide comprises non-conductive zones which electrically insulate guide holes by the at least one conductive portion so that the guide holes are not short-circuited by the at least one conductive portion.
